(19) United States
(12) Patent Application Publication
(10) Pub. No.: US 2015/0171011 A1
(43) Pub. Date: Jun. 18, 2015

(54) SEMICONDUCTOR DEVICE AND MANUFACTURING METHOD THEREOF

(71) Applicant: Kabushiki Kaisha Toshiba, Minato-Ku (JP)

(72) Inventor: Atsushi Kato, Yokkaichi-Shi (JP)

(73) Assignee: KABUSHIKI KAISHA TOSHIBA, Minato-Ku (JP)

(21) Appl. No.: 14/197,832

(22) Filed: Mar. 5, 2014

Related U.S. Application Data
(60) Provisional application No. 61/915,787, filed on Dec. 13, 2013.

(51) Int. Cl. H01L 23/522; H01L 23/532; H01L 21/768

(52) U.S. Cl. CPC H01L 23/5226; H01L 21/76879; H01L 23/53228; H01L 23/53257

(57) ABSTRACT

A semiconductor device according to the present embodiment includes a first insulating film above a substrate. Contact plugs are located in contact holes passing through the first insulating film, respectively. The contact plugs have upper surfaces at positions lower than an upper surface of the first insulating film, respectively. Wires are located on the upper surface of the first insulating film. The wires are located at positions lower than the upper surface of the first insulating film to connect to upper surfaces of the contact plugs at positions of the contact holes, respectively.

### CROSS REFERENCE TO RELATED APPLICATIONS

This application is based upon and claims the benefit of priority from the prior U.S. Provisional Patent Application No. 61/915,787, filed on Dec. 13, 2013, the entire contents of which are incorporated herein by reference.

### FIELD

The embodiments of the present invention relate to a semiconductor device and manufacturing method thereof.

### BACKGROUND

Via contacts and wires of a semiconductor device are used to electrically connect semiconductor elements, lower layer wires, upper layer wires, and the like to each other. For example, via contacts formed in an interlayer dielectric film electrically connect semiconductor elements or lower layer wires provided under the interlayer dielectric film to upper layer wires provided on the interlayer dielectric film, respectively.

These upper layer wires are generally formed by a lithographic technique and an etching technique or a damascene method. At that time, the upper layer wires are displaced from positions of via contacts corresponding to the upper layer wires, respectively, in some cases. In these cases, adjacent other upper layer wires may come close to the via contacts. If distances between other upper layer wires and the via contacts are too small, withstand pressures between other upper layer wires and the via contacts are reduced or other upper layer wires and the via contact may be short-circuited, respectively.

### BRIEF DESCRIPTION OF THE DRAWINGS

FIG. 1A is a plan view showing an example of a configuration of a semiconductor device 100 according to the present embodiment;

FIG. 1B is a cross-sectional view taken along a line B-B in FIG. 1A;

FIG. 2 shows positions of the wires 70 displaced in the direction D2 from the contact plugs 40 corresponding to the wires 70, respectively; and

FIGS. 3A to 4B are cross-sectional views showing an example of a manufacturing method of the semiconductor device 100 according to the present embodiment.

### DETAILED DESCRIPTION

Embodiments will now be explained with reference to the accompanying drawings. The present invention is not limited to the embodiments. In the embodiments, “an upper direction” or “a lower direction” refers to a relative direction when a direction of a surface of a semiconductor substrate on which semiconductor elements are provided is assumed as “an upper direction”. Therefore, the term “upper direction” or “lower direction” occasionally differs from an upper direction or a lower direction based on a gravitational acceleration direction.

A semiconductor device according to the present embodiment includes a first insulating film above a substrate. Contact plugs are located in contact holes passing through the first insulating film, respectively. The contact plugs have upper surfaces at positions lower than an upper surface of the first insulating film, respectively. Wires are located on the upper surface of the first insulating film. The wires are located at positions lower than the upper surface of the first insulating film to connect to upper surfaces of the contact plugs at positions of the contact holes, respectively.

A NAND flash memory as an example of the semiconductor device according to the present embodiment is explained below. However, the present embodiment is not limited to a memory and is applicable to other semiconductor devices.

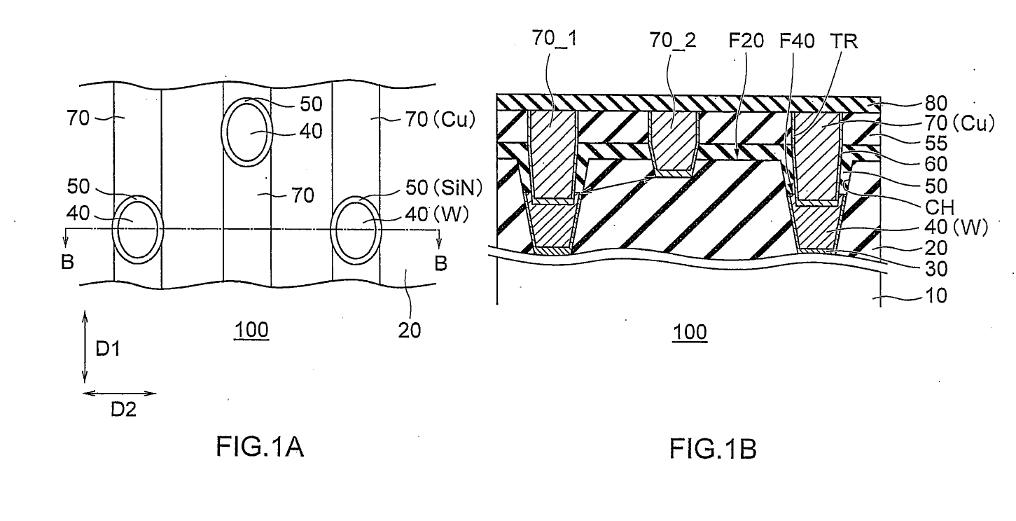

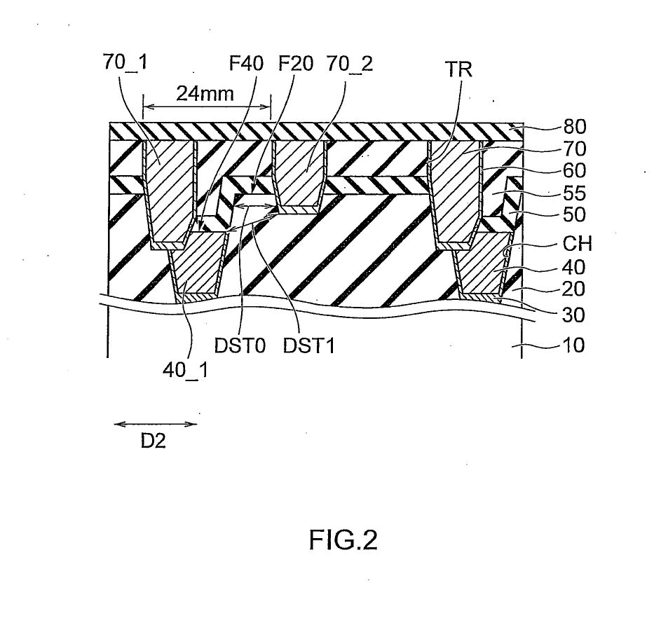

FIG. 1A is a plan view showing an example of a configuration of a semiconductor device 100 according to the present embodiment. In FIG. 1A, layers above contact plugs and wires 70 are omitted to clearly show positional relationships between the contact plugs 40 and the wires 70. FIG. 1B is a cross-sectional view taken along a line B-B in FIG. 1A. The semiconductor device 100 can be, for example, a NAND flash memory (hereinafter, also simply “memory”). Wires according to the present embodiment are applicable to, for example, bit lines in a memory area.

The semiconductor device 100 according to the present embodiment includes a substrate 10, an interlayer dielectric film 20 serving as a first insulating film, a barrier film 30, contact plugs 40, a stopper dielectric film 50, an interlayer dielectric film 55, a barrier film 60, wires 70, and a cap dielectric film 80 as shown in FIG. 1B.

The substrate 10 is, for example, a semiconductor substrate such as a silicon substrate. Semiconductor elements such as memory cells and peripheral circuits are arranged in a memory area on the substrate 10. The interlayer dielectric film 20 is provided above the substrate 10 to cover the semiconductor elements. The interlayer dielectric film 20 is formed using, for example, an insulating film such as a silicon dioxide film or a silicon nitride film. The interlayer dielectric film 20 can be provided on lower layer wires (not shown) on the semiconductor elements.

Contact holes CH are provided to pass through the interlayer dielectric film 20. The contact holes CH are formed from an upper surface of the interlayer dielectric film 20 to reach the semiconductor elements or the lower layer wires. The contact holes CH are formed in tapered shapes to have openings extending from the interlayer dielectric film 20 toward the interlayer dielectric film 55 (extending toward an upper side), respectively.

The barrier film 30 is formed on bottom surfaces and side surfaces of the contact holes CH. The barrier film 30 is formed using, for example, a conductive material such as titanium, tantalum, or TaN.

The contact plugs 40 are provided in the contact holes CH and pass through the interlayer dielectric film 20 to be electrically connected to the semiconductor elements or the lower layer wires, respectively. The contact plugs 40 are formed using, for example, a conductive metal such as tungsten. Accordingly, the contact plugs 40 are electrically connected to the semiconductor elements or the lower layer wires under the interlayer dielectric film 20, respectively. The barrier film 30 and the contact plugs 40 are provided in bottom parts of the contact holes CH and are not filled up to upper parts (near the openings) of the contact holes CH. That is, upper surfaces F40 of the barrier film 30 and the contact plugs 40 are located at a position lower (a position nearer to the substrate 10) than an upper surface F20 of the interlayer dielectric film 20. This enables to keep a distance DST1 between a contact plug 40 and a wire 70_2 large even when a wire 70_1 is displaced, as explained later.

The contact plugs 40 provided for the wires 70 adjacent to each other are located at positions shifted in an extension direction D1 of the wires 70, respectively, as shown in FIG. 1A. Accordingly, even when widths of the contact plugs 40 in a direction D2 (a direction substantially orthogonal to the direction D1) are rather large, the contact plugs 40 provided for the wires 70 adjacent to each other are not short-circuited.

The stopper dielectric film 50 is provided on the interlayer dielectric film 20. The stopper dielectric film 50 is formed using, for example, an insulating film such as a silicon nitride film. Because the upper surfaces F40 of the barrier film 30 and the contact plugs 40 are located at positions lower than the upper surface F20 of the interlayer dielectric film 20, the stopper dielectric film 50 penetrates into the contact holes CH toward the barrier film 30 and the contact plugs 40.

The interlayer dielectric film 55 is provided on the stopper dielectric film 50. The interlayer dielectric film 55 is formed using, for example, an insulating film such as a silicon dioxide film (TEOS (Tetraethylorthosilicate), for example). While the stopper dielectric film 50 penetrates into the contact holes CH in FIG. 1B, the interlayer dielectric film 55 also can penetrate into the contact holes CH.

The barrier film 60 is provided on bottom surfaces and side surfaces of trenches TR formed in the interlayer dielectric film 55 and the stopper dielectric film 50. The barrier film 60 is formed using, for example, a conductive material such as titanium, tantalum, or TaN, similarly to the barrier film 30.

The wires 70 are embedded in the trenches TR, respectively. The wires 70 are provided on the barrier film 60 in the trenches TR, respectively. The wires 70 extend in the direction D1 and are formed in strip shapes, as shown in FIG. 1A. The wires 70 are formed using, for example, a metal such as copper.

In areas of the interlayer dielectric film 20 other than those where the contact holes CH are formed, the wires 70 are provided on the interlayer dielectric film 20. The wires 70 are provided at positions lower than the upper surface F20 of the interlayer dielectric film 20 to connect to the upper surfaces of the contact plugs 40 at positions of the contact holes CH. Parts (70_1) of the wires 70 provided at the positions of the contact holes CH are formed up to positions deeper than parts (70_2) of the wires 70 provided on the interlayer dielectric film 20.

The cap dielectric film 80 is provided on the interlayer dielectric film 55 and the wires 70. The cap dielectric film 80 is formed using, for example, an insulating film such as a silicon nitride film.

Other interlayer dielectric films, contact plugs, wires, and the like (not shown) are provided on the cap dielectric film 80.

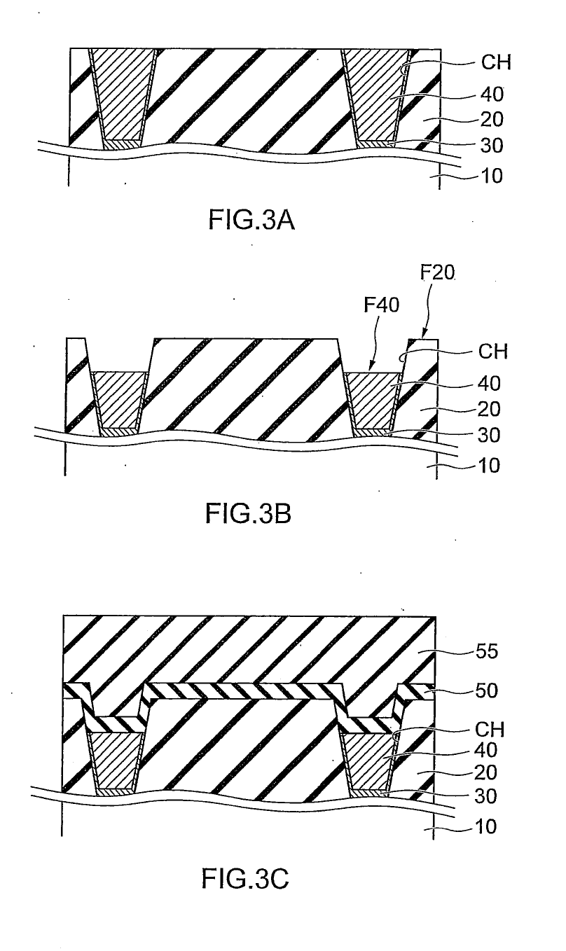

FIG. 2 shows positions of the wires 70 displaced in the direction D2 from the contact plugs 40 corresponding to the wires 70, respectively. If misalignment occurs in a lithographic process while the wires 70 or the trenches TR are formed, the wires 70 are displaced from the contact plugs 40 (or the contact holes CH) corresponding thereto, respectively, as shown in FIG. 2.

For example, the wire 70_1 is displaced from a contact plug 40_1 corresponding thereto. In this case, the wire 70_2 adjacent to the wire 70_1 becomes closer to the contact plug 40_1.

If the contact plugs 40 are filled in the entire contact holes CH to be embedded up to the upper surface F20 of the interlayer dielectric film 20, a distance between the contact plug 40_1 and the wire 70_2 is DST0.

On the other hand, in the present embodiment, the upper surfaces F40 of the contact plugs 40 (and the barrier film 30) are located at the position lower than the upper surface F20 of the interlayer dielectric film 20. Therefore, a distance between the contact plug 40_1 and the wire 70_2 is DST1, which is larger than DST0. Accordingly, even when the wire 70_1 is displaced in the direction D2, the distance DST1 between the contact plug 40_1 and the wire 70_2 can be kept large. As a result, the semiconductor device 100 according to the present embodiment can keep withstand pressures between the wires 70 and the contact plugs 40 or withstand pressures between adjacent ones of the wires 70 high.

Downscaling of the memory area has progressed in recent years and intervals between adjacent bit lines have become quite small. Therefore, withstand pressures between the bit lines may be lower than a reference value if misalignment of the bit lines occurs.

Specifically, a case where a minimum distance between bit lines and adjacent contacts meeting a withstand pressure specification is about 7 nanometers and a misalignment value is about ±10 nanometers is considered. A half pitch of the wires 70 is about 12 nanometers (a pitch is about 24 nanometers), for example. In this case, if misalignment occurs, the distance DST0 is about 2 nanometers, which is quite smaller than the minimum distance (about 7 nanometers). In such a case, the withstand pressures between the bit lines and the adjacent contacts cannot meet the specification.

On the other hand, when the upper surfaces F40 of the contact plugs 40 are retracted to set a difference in heights between the upper surfaces F40 of the contact plugs 40 and the bottom surfaces of the wires 70 on the interlayer dielectric film 20 at, for example, a value equal to or larger than about 6.7 nanometers as in the present embodiment, the distance DST1 is equal to or larger than about 7 nanometers and the withstand pressures between the bit lines and the adjacent contacts can meet the specification. At that time, when a distance between the upper surface F20 of the interlayer dielectric film 20 and the bottom surfaces of the wires 70 is about 5 nanometers, a difference in heights between the upper surface F40 of the contact plugs 40 and the upper surface F20 of the interlayer dielectric film 20 is, for example, about 11.7 (6.7+5) nanometers. That is, in this specific example, the withstand pressures between the bit lines and the adjacent contacts can meet the specification when the difference in heights between the upper surface F40 of the contact plugs 40 and the upper surface F20 of the interlayer dielectric film 20 is equal to or larger than about 11.7 nanometers. This specific example is merely illustrative and of course differs according to products, specifications, generations, shapes, and the like.

As described above, according to the present embodiment, the distances DST1 between the contact plugs 40 and the wires 70 adjacent thereto and the withstand pressures therebetween can be controlled by controlling depths (positions of the upper surfaces F40) of the contact plugs 40, respectively. As a result, the semiconductor device 100 according to the present embodiment can suppress reductions in the withstand pressures between the wires 70 and the corresponding contact plugs 40 and shorts therebetween.

When the wires 70 cover only parts of the upper surfaces F40 of the contact plugs 40 due to wire displacement, respectively, as in FIG. 2, the stopper dielectric film 50 and the interlayer dielectric film 55 cover the remaining parts of the upper surfaces F40 of the contact plugs 40. Therefore, even when the wires 70 are displaced to some extent, the stopper dielectric film 50 and the interlayer dielectric film 55 cover the insides of the contact holes CH and thus no problems occur in the withstand pressures between the wires 70 and the contact plugs 40.

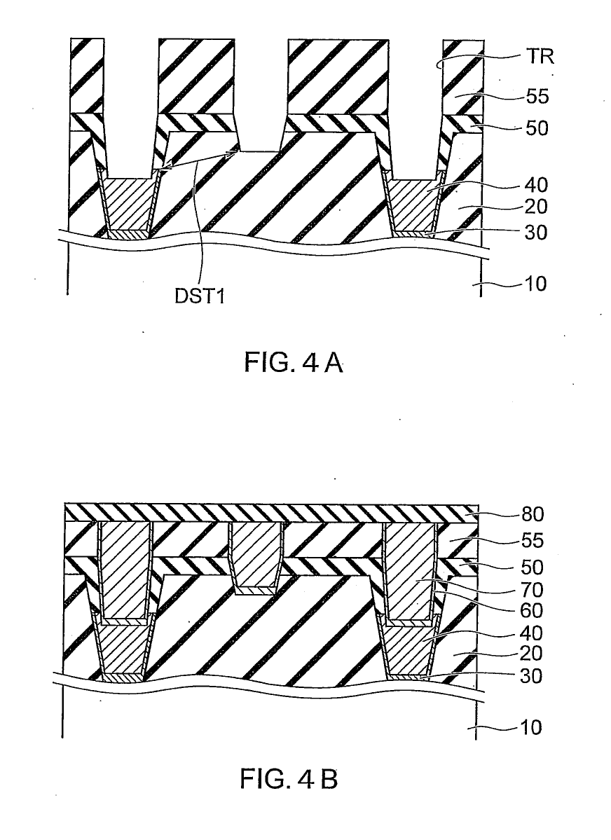

FIGS. 3A to 4B are cross-sectional views showing an example of a manufacturing method of the semiconductor device 100 according to the present embodiment.

Semiconductor elements (not shown) are first formed on the substrate 10 using a semiconductor processing technique. For example, semiconductor elements such as memory cells MC are formed in the memory area. Other semiconductor elements such as transistors, capacitors, and resistors are formed in a peripheral circuit area 2 (not shown).

The interlayer dielectric film 20 is then formed above the substrate 10 to cover the semiconductor elements. The contact holes CH are then formed in the interlayer dielectric film 20 using the lithographic technique and an etching technique. The contact holes CH pass through the interlayer dielectric film 20 to reach the semiconductor elements on the substrate 10. The contact holes CH are formed in the tapered shapes in such a manner that the openings of the contact holes CH extend from the interlayer dielectric film 20 toward the interlayer dielectric film 55.

Materials of the barrier film 30 and the contact plugs 40 are then deposited in the contact holes CH and on the interlayer dielectric film 20. The material of the barrier film 30 is, for example, titanium, tantalum, or TaN and the material of the contact plugs 40 is, for example, tungsten.

The barrier film 30 and the contact plugs 40 are then polished using a CMP (Chemical Mechanical Polishing) method until the upper surface of the interlayer dielectric film 20 is exposed. In this way, a structure shown in FIG. 3A is obtained.

The material of the contact plugs 40 (tungsten, for example) is then selectively etched back as shown in FIG. 3B. That is, upper parts of the material of the contact plugs 40 are removed to set the upper surfaces F40 of the contact plugs 40 to be lower than the upper surface F20 of the interlayer dielectric film 20.

The stopper dielectric film 50 and the interlayer dielectric film 55 are then deposited on the contact plugs 40 and on the interlayer dielectric film 20 as shown in FIG. 3C. At that time, because the contact plugs 40 are etched back to positions deeper than the upper surface of the interlayer dielectric film 20, the stopper dielectric film 50 covers the upper surfaces F40 of the contact plugs 40 and also covers upper side surfaces of the contact holes CH. The interlayer dielectric film 55 is filled in the contact holes CH with the stopper dielectric film 50 interposed therebetween.

The trenches TR are then formed in the interlayer dielectric film 55 and the stopper dielectric film 50 using the lithographic technique and an etching technique (an RIE (Reactive Ion Etching) method, for example). As shown in FIG. 4A, the trenches TR are formed to reach the corresponding contact plugs 40, respectively. The trenches TR are formed in a layout pattern of the wires 70 (see FIG. 1A). At that time, the stopper dielectric film 50 functions as an etching stopper. For example, in the etching process, etching is stopped when the material (tungsten, for example) of the contact plug 40 is detected after a material (a silicon nitride film, for example) of the stopper dielectric film 50 is detected. In this way, the trenches TR reaching the contact plugs 40 can be formed without excessive overetching.

The inner surfaces of the trenches TR are then coated by a material of the barrier film 60 and then a material (copper, for example) of the wires 70 is deposited in the trenches TR and on the interlayer dielectric film 55. The materials of the wires 70 and the barrier film 60 are then polished using the CMP method until the surface of the interlayer dielectric film 55 is exposed. The cap dielectric film 80 is then deposited on the wires 70 and the interlayer dielectric film 55. In this way, a structure shown in FIG. 4B is obtained.

Other interlayer dielectric films, contact plugs, and wires are then formed, thereby completing the semiconductor device 100 according to the present embodiment.

According to the present embodiment, the contact plugs 40 are etched back to the positions deeper than the upper surface F20 of the interlayer dielectric film 20. This enables the distances (DST1 in FIG. 4A) between the contact plugs 40 and the wires 70 adjacent thereto to be formed sufficiently large. Therefore, even when the contact holes CH have tapered portions and the opening portions are formed large, the withstand pressure between the contact plug 40_1 and the wire 70_2 adjacent thereto can be kept high.

Even when misalignment occurs in lithography during formation of the trenches TR, the withstand pressure between the contact plug 40_1 and the wire 70_2 adjacent thereto can be kept high because the distance DST1 is sufficiently large.

That is, according to the present embodiment, the distances DST1 between the contact plugs 40 and the wires 70 adjacent thereto and the withstand pressures therebetween can be controlled by controlling the depths (the positions of the upper surface F40) of the contact plugs 40, respectively. As a result, the semiconductor device 100 according to the present embodiment can suppress reductions in the withstand pressures between the wires 70 and the contact plugs 40 and shorts therebetween.

When the wires 70 over only parts of the upper surfaces F40 of the contact plugs 40 due to wire displacement, respectively, as in FIG. 2, the stopper dielectric film 50 and the interlayer dielectric film 55 cover the remaining parts of the upper surfaces F40 of the contact plugs 40. Therefore, no problems occur in the withstand pressures between the wires 70 and the contact plugs 40.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a first insulating film above a substrate;
contact plugs being in contact holes passing through the first insulating film and having upper surfaces at positions lower than an upper surface of the first insulating film, respectively, and
wires on the upper surface of the first insulating film, the wires being at positions lower than the upper surface of the first insulating film to connect to upper surfaces of the contact plugs at positions of the contact holes, respectively.

2. The device of claim 1, wherein portions of the wires being at the positions of the contact holes are formed up to positions deeper than portions of the wires on the first insulating film.

3. The device of claim 1, further comprising a second insulating film on the wires and on the first insulating film, wherein
when the wires cover only parts of the upper surfaces of the contact plugs, the second insulating film covers remaining parts of the upper surfaces of the contact plugs.

4. The device of claim 2, further comprising a second insulating film on the wires and on the first insulating film, wherein
when the wires cover only parts of the upper surfaces of the contact plugs, the second insulating film covers remaining parts of the upper surfaces of the contact plugs.

5. The device of claim 1, wherein the contact holes have tapered shapes to have openings of the contact holes extending from the first insulating film toward the second insulating film, respectively.

6. The device of claim 1, wherein
the contact plugs are made of tungsten, and
the wires are made of copper.

7. A manufacturing method of a semiconductor device, the method comprising:
forming a first insulating film above a substrate;
forming contact holes passing through the first insulating film;
embedding a material of contact plugs in the contact holes;
removing the material of the contact plugs up to positions lower than an upper surface of the first insulating film; and
forming wires on the first insulating film and on the contact plugs.

8. The method of claim 7, wherein the wires penetrate into positions lower than the upper surface of the first insulating film to connect to upper surfaces of the contact plugs at positions of the contact holes, respectively.

9. The method of claim 7, wherein portions of the wires being at the positions of the contact holes are formed up to positions deeper than portions of the wires on the first insulating film.

10. The method of claim 7, further comprising forming a second insulating film on the wires and on the first insulating film, wherein
when the wires cover only parts of the upper surfaces of the contact plugs, the second insulating film covers remaining parts of the upper surfaces of the contact plugs.

11. The method of claim 8, further comprising a second insulating film on the wires and on the first insulating film, wherein
when the wires cover only parts of the upper surfaces of the contact plugs, the second insulating film covers remaining parts of the upper surfaces of the contact plugs.

12. The method of claim 9, further comprising a second insulating film on the wires and on the first insulating film, wherein
when the wires cover only parts of the upper surfaces of the contact plugs, the second insulating film covers remaining parts of the upper surfaces of the contact plugs.

13. The method of claim 7, wherein the contact holes have tapered shapes to have openings of the contact holes extending from the first insulating film toward the second insulating film, respectively.

14. The method of claim 8, wherein the contact holes have tapered shapes to have openings of the contact holes extending from the first insulating film toward the second insulating film, respectively.

15. The method of claim 9, wherein the contact holes have tapered shapes to have openings of the contact holes extending from the first insulating film toward the second insulating film, respectively.

16. The method of claim 7, wherein
the contact plugs are made of tungsten, and
the wires are made of copper.

17. The method of claim 7, wherein
the forming of the wires comprises:
depositing a second insulating film on the first insulating film and on the contact plugs;
processing the second insulating film to form trenches in areas of the wires;
embedding a material of the wires in the trenches; and
polishing the material of the wires.
